(19) United States
(12) Patent Application Publication
(10) Pub. No.: US 2021/0408430 A1
(43) Pub. Date: Dec. 30, 2021

(54) LIGHT EMITTING PANEL, METHOD FOR MANUFACTURING LIGHT EMITTING PANEL, AND DISPLAY DEVICE

(71) Applicant: WUHAN CHINA STAR OPTOELECTRONICS SEMICONDUCTOR DISPLAY TECHNOLOGY CO., LTD., Wuhan (CN)

(72) Inventor: Hanning YANG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/768,885

(22) PCT Filed: Nov. 25, 2019
(86) PCT No.: PCT/CN2019/120487

§ 371 Date: Jun. 2, 2020

(30) Foreign Application Priority Data
Aug. 27, 2019 (CN) 201910798239.0

(51) Int. Cl. H01L 51/52; G06F 3/041; H01L 51/56

(52) U.S. Cl. CPC H01L 51/52; G06F 3/041; H01L 27/3244; G06F 2203/04103; H01L 2251/5338; H01L 51/56

(57) ABSTRACT

A light emitting panel, a method for manufacturing a light emitting panel, and a display device are provided. The light emitting panel includes: a substrate, a flexible layer, a light emitting device, and a cover plate which are sequentially stacked up from bottom to top; wherein a rough structure is formed on one surface of the flexible layer facing the substrate, and the rough structure includes a plurality of concave portions which are arranged. Mechanical damages or wrinkles among layers during a bending process can be decreased when the light emitting panel is bent, and yield rate of the light emitting panel can be increased.

### TECHNICAL FIELD

The present disclosure relates to a technology field of displays, and more particularly to a light emitting panel, a method for manufacturing a light emitting panel, and a display device.

### BACKGROUND

Recent years, organic light emitting diodes (OLEDs) have advantageous features of self-luminance, low power consumption, a wide viewing angle, various colors, and a fast response and can be manufactured as a flexible screen. Accordingly, the OLEDs are interesting in scientific searches and industries and considered to be next generation display techniques with high potential.

In the prior art, mechanical characteristics of different films are different. When a light emitting panel is bent, a neutral layer is not positioned in a matrix layer or a light emitting layer. The matrix layer or the light emitting layer easily has mechanical damages and display quality is affected when being bent continuously. Furthermore, a flexible layer under the matrix layer has high Young's modulus, and thus the flexible layer easily has mechanical damages or wrinkles, so that the display quality of the light emitting panel is poor.

Consequently, the prior art has defects and needs to be improved.

### SUMMARY OF DISCLOSURE

Embodiments of the present disclosure provide a light emitting panel and a display device capable of decreasing mechanical damages or wrinkles among layers during a bending process when the light emitting panel is bent and increasing yield rate of the light emitting panel.

In a first aspect, an embodiment of the present disclosure provides a light emitting panel, including: a substrate, a flexible layer, a light emitting device, and a cover plate which are sequentially stacked up from bottom to top; wherein a rough structure is formed on one surface of the flexible layer facing the substrate, and the rough structure includes a plurality of concave portions which are arranged.

In the light emitting panel of the present disclosure, an interval is formed between two adjacent ones of the concave portions.

In the light emitting panel of the present disclosure, a density of the concave portions on the flexible layer is ranged from 10⁴ to 10⁸ per square centimeter, a length of a first opening of each of the concave portions in a horizontal direction is ranged from 1 nanometer to 5000 nanometers, and a length of a second opening of each of the concave portions in a vertical direction is ranged from 100 nanometers to 5000 nanometers.

In the light emitting panel of the present disclosure, a section shape of each of the concave portions is one of an arc, a circle, a square, and a trapezoid.

In the light emitting panel of the present disclosure, a touch panel and a polarizer are disposed between the light emitting device and the cover plate, and the polarizer is disposed on the touch panel.

In a second aspect, an embodiment of the present disclosure provides a method for manufacturing a light emitting panel, including: providing a base; forming a flexible layer on the base, and forming nanoparticles in a bottom of the flexible layer; forming a light emitting device on the flexible layer; irradiating the base by laser light to form carbides in the bottom of the flexible layer surrounding the nanoparticles, and peeling off the carbides and the base to form a rough structure on one surface of the flexible layer; and adhering a substrate on the bottom of the flexible layer, and sequentially stacking up a touch panel, a polarizer, and a cover plate on the light emitting device to form the light emitting panel.

In the method for manufacturing the light emitting panel of the present disclosure, the step of forming the flexible layer on the base and the step of forming the nanoparticles in the bottom of the flexible layer include: coating a solution having the nanoparticles doped therein on the base, and curing the solution to form the nanoparticles in the bottom of the flexible layer.

In the method for manufacturing the light emitting panel of the present disclosure, before the step of adhering the substrate on the bottom of the flexible layer and the step of sequentially stacking up the touch panel, the polarizer, and the cover plate on the light emitting device to form the light emitting panel, the method further includes: cleaning the bottom of the flexible layer to eliminate the nanoparticles.

In the method for manufacturing the light emitting panel of the present disclosure, a section shape of each of the carbides is one of an arc, a circle, a square, and a trapezoid.

In a third aspect, an embodiment of the present disclosure provides a display device including a housing and a light emitting panel disposed on the housing, and the light emitting panel includes: a substrate, a flexible layer, a light emitting device, and a cover plate which are sequentially stacked up from bottom to top; wherein a rough structure is formed on one surface of the flexible layer facing the substrate, and the rough structure includes a plurality of concave portions which are arranged.

In the display device of the present disclosure, an interval is formed between two adjacent ones of the concave portions.

In the display device of the present disclosure, a density of the concave portions on the flexible layer is ranged from 10⁴ to 10⁸ per square centimeter, a length of a first opening of each of the concave portions in a horizontal direction is ranged from 1 nanometer to 5000 nanometers, and a length of a second opening of each of the concave portions in a vertical direction is ranged from 100 nanometers to 5000 nanometers.

In the display device of the present disclosure, a section shape of each of the concave portions is one of an arc, a circle, a square, and a trapezoid.

In the display device of the present disclosure, a touch panel and a polarizer are disposed between the light emitting device and the cover plate, and the polarizer is disposed on the touch panel.

An embodiment of the present disclosure further provides a light emitting panel, including: a substrate, a flexible layer, a light emitting device, and a cover plate which are sequentially stacked up from bottom to top; wherein a rough structure is formed on one surface of the flexible layer facing the substrate, and the rough structure includes a plurality of concave portions which are arranged; wherein an interval is formed between two adjacent ones of the concave portions, a touch panel and a polarizer are disposed between the light emitting device and the cover plate, and the polarizer is disposed on the touch panel.

The light emitting panel provided by the embodiment of the present disclosure includes a substrate, a flexible layer, a light emitting device, and a cover plate which are sequentially stacked up from bottom to top. A rough structure is formed on one surface of the flexible layer facing the substrate, and the rough structure includes a plurality of concave portions which are arranged. Mechanical damages or wrinkles among layers during a bending process can be decreased by changing the position of the stress neutral surface when the light emitting panel is bent. Yield rate of the light emitting panel can be increased.

### BRIEF DESCRIPTION OF DRAWINGS

In order to more clearly illustrate the embodiments or the technical schemes in the prior art, the following drawings of the embodiments or in the prior art will be briefly introduced. It is obvious that the drawings are merely some embodiments of the present disclosure, and one of ordinary skill in the art may derive other drawings according the drawings described below without creative endeavor.

FIG. 1 illustrates a structure diagram of a display device provided by an embodiment of the present disclosure.

FIG. 2 illustrates a first structure diagram of a light emitting panel provided by an embodiment of the present disclosure.

FIG. 3 illustrates a first structure diagram of a flexible layer in the light emitting panel provided by an embodiment of the present disclosure.

FIG. 4 illustrates a second structure diagram of the flexible layer in the light emitting panel provided by an embodiment of the present disclosure.

FIG. 5 illustrates a second structure diagram of the light emitting panel provided by an embodiment of the present disclosure.

FIG. 6 illustrates a flow chart of a method for manufacturing a light emitting panel provided by an embodiment of the present disclosure.

### DETAILED DESCRIPTION OF EMBODIMENTS

A clear and complete description of the technical schemes in the embodiments of the present disclosure is made in conjunction with the accompanying drawings in the embodiments of the present disclosure. The described embodiments are merely a part and not all of the embodiments of the present disclosure. Based on the embodiments of the present disclosure, all other embodiments acquired by one of ordinary skill in the art without any inventive efforts are within the scope of protection of the present disclosure.

In the prior art, mechanical characteristics of different films are different. When a light emitting panel is bent, a neutral layer is not positioned in a matrix layer or a light emitting layer. The matrix layer or the light emitting layer easily has mechanical damages and display quality is affected when being bent continuously. Furthermore, a flexible layer under the matrix layer has high Young's modulus, and thus the flexible layer easily has mechanical damages or wrinkles, so that the display quality of the light emitting panel is poor.

An embodiment of the present disclosure provides a display device including a housing and a light emitting panel disposed on the housing. The light emitting panel includes a substrate, a flexible layer, a light emitting device, and a cover plate which are sequentially stacked up from bottom to top.

A rough structure is formed on one surface of the flexible layer facing the substrate, and the rough structure includes a plurality of concave portions which are arranged.

An interval is formed between two adjacent ones of the concave portions.

A density of the concave portions on the flexible layer is ranged from 10⁴ to 10⁸ per square centimeter. A length of a first opening of each of the concave portions in a horizontal direction is ranged from 1 nanometer to 5000 nanometers. A length of a second opening of each of the concave portions in a vertical direction is ranged from 100 nanometers to 5000 nanometers.

A section shape of each of the concave portions is one of an arc, a circle, a square, and a trapezoid.

A touch panel and a polarizer are disposed between the light emitting device and the cover plate, and the polarizer is disposed on the touch panel.

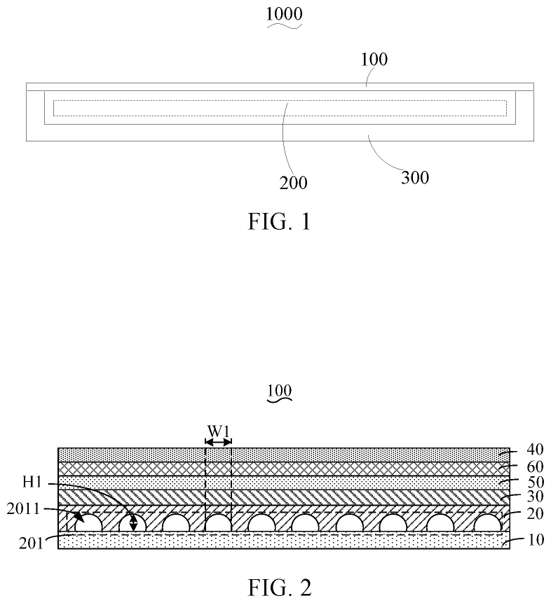

Please refer to FIG. 1. FIG. 1 illustrates a structure diagram of a display device 1000 provided by an embodiment of the present disclosure. The display device 1000 may include a light emitting panel 100, a control circuit 200, and a housing 300. It is noted that the display device 1000 in FIG. 1 is not limited to the above-mentioned elements and can be further include other devices, such as a camera, an antenna structure, and a fingerprint unlock module.

The light emitting panel 100 is disposed on the housing 300.

In some embodiments, the light emitting panel 100 may be fixed to the housing 300. An enclosed space is formed between the light emitting panel 100 and the housing 300 to contain the control circuit 200 and other device.

In some embodiments, the housing 300 may be manufactured of a flexible material, for example, a plastic housing or a silicone housing.

The control circuit 200 is assembled in the housing 300. The control circuit 200 may be a mainboard of the display device 1000. One, two, or more of a battery, an antenna structure, a microphone, a loudspeaker, an earphone jack, a universal serial bus interface, a camera, a distance sensor, an ambient light sensor, a receiver, and a processor.

The light emitting panel 100 is assembled in the housing 300. The light emitting panel 100 is electrically connected to the control circuit 200 to form as display surface of the display device 1000. The light emitting panel 100 may include a display area and a non-display area. The display area may display an image of the display device 1000 or be provided for a user to perform a touch operation.

An embodiment of the present disclosure further provides a light emitting panel including a substrate, a flexible layer, a light emitting device, and a cover plate which are sequentially stacked up from bottom to top.

A rough structure is formed on one surface of the flexible layer facing the substrate, and the rough structure includes a plurality of concave portions which are arranged.

An interval is formed between two adjacent ones of the concave portions.

A density of the concave portions on the flexible layer is ranged from 10⁴ to 10⁸ per square centimeter. A first opening length of each of the concave portions in a horizontal direction is ranged from 1 nanometer to 5000 nanometers. A second opening length of each of the concave portions in a vertical direction is ranged from 100 nanometers to 5000 nanometers.

A section shape of each of the concave portions is one of an arc, a circle, a square, and a trapezoid.

A touch panel and a polarizer are disposed between the light emitting device and the cover plate, and the polarizer is disposed on the touch panel.

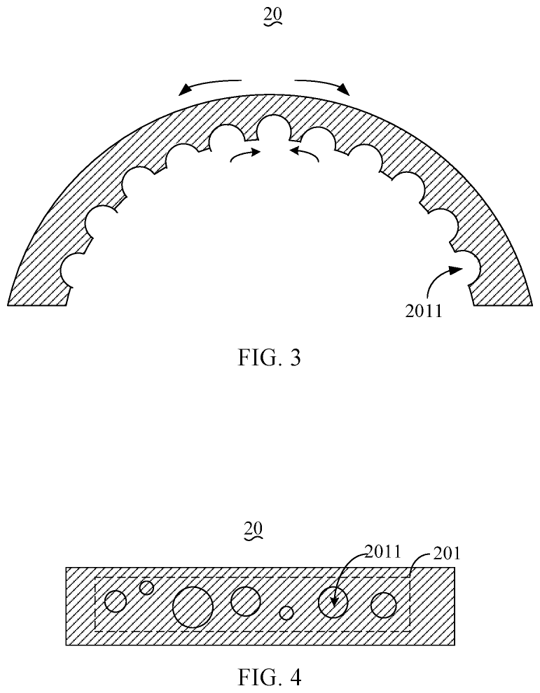

Please refer to FIG. 2 and FIG. 3. FIG. 2 illustrates a first structure diagram of a light emitting panel provided by an embodiment of the present disclosure. FIG. 3 illustrates a first structure diagram of a flexible layer in the light emitting panel provided by an embodiment of the present disclosure. The light emitting panel 100 includes a substrate 10, a flexible layer 20, a light emitting device 30, and a cover plate 40 which are sequentially stacked up from bottom to top.

A rough structure 201 is formed on one surface of the flexible layer 20 facing the substrate 10, and the rough structure includes a plurality of concave portions 2011 which are arranged.

It can be understood from FIG. 3 that when the light emitting panel 100 is bent, the flexible layer 20 is also bent due to effect of a bending force. The flexible material around the concave portions 2011 fills toward insides of the concave portions 2011. That is, the concave portions 2011 can decrease compressive force of the flexible layer 20. A stress neutral surface can be adjusted to the light emitting device 30 or other layer on the light emitting device 30 by decreasing the compressive force of the flexible layer 20 when the light emitting panel 100 is bent.

The light emitting device 30 is configured to emit light, so that the light emitting panel 100 displays an image. Herein, the light emitting device 30 may include a thin film transistor (TFT) and an organic light emitting diode (OLED) which are not shown.

Generally, the flexible layer 20 is manufactured of polyimide (PI) organic macromolecule material and bendable.

A touch panel 50 and a polarizer 60 are disposed between the light emitting device 30 and the cover plate 40, and the polarizer 60 is disposed on the touch panel 50. The touch panel 50 is configured to implement a touch function of the light emitting panel 100. The touch panel 50 may be adhered to the light emitting device 30 via an optically clear adhesive (OCA). The polarizer 60 is configured to let polarized light pass to form an image from the light emitted by the light emitting device 30.

In some embodiments, an interval is formed between two adjacent ones of the concave portions 2011 and configured to support the flexible layer 20 on the substrate 10.

It can be understood that the intervals are formed between any two adjacent ones of the concave portions 2011 to prevent the flexible layer 20 on the substrate 10 from being bent or tilted. As such, the flexible layer 20 can be supported on the substrate 10 via the intervals.

Please refer to FIG. 1 and FIG. 4. FIG. 4 illustrates a second structure diagram of the flexible layer in the light emitting panel provided by an embodiment of the present disclosure. In some embodiments, a density of the concave portions 2011 on the flexible layer 20 is ranged from 10⁴ to 10⁸ per square centimeter. A first opening length W1 of each of the concave portions 2011 in a horizontal direction is ranged from 1 nanometer to 5000 nanometers. A second opening length H1 of each of the concave portions 2011 in a vertical direction is ranged from 100 nanometers to 5000 nanometers.

The first opening length W1 of each of the concave portions 2011 may be different from the second opening length H1 of each of the concave portions 2011. The intervals between any two adjacent ones of the concave portions 2011 may be different as well.

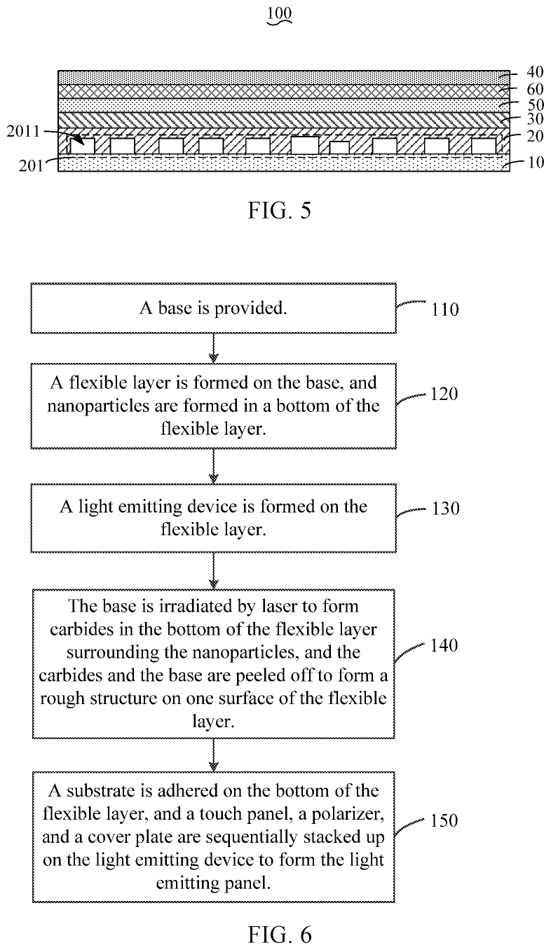

FIG. 5 illustrates a second structure diagram of the light emitting panel provided by an embodiment of the present disclosure. As shown in FIG. 5, in some embodiments, as shown in FIG. 5, a section shape of each of the concave portions 2011 is one of an arc, a circle, a square, and a trapezoid.

The light emitting panel 100 provided by the embodiment of the present disclosure includes a substrate 10, a flexible layer 20, a light emitting device 30, and a cover plate 40 which are sequentially stacked up from bottom to top. A rough structure 201 is formed on one surface of the flexible layer 20 facing the substrate 10, and the rough structure 201 includes a plurality of concave portions 2011 which are arranged. Mechanical damages or wrinkles among layers during a bending process can be decreased by changing the position of the stress neutral surface when the light emitting panel 100 is bent. Yield rate of the light emitting panel can be increased.

An embodiment of the present disclosure further provides a method for manufacturing a light emitting panel. The method includes:

providing a base;

forming a flexible layer on the base, and forming nanoparticles in a bottom of the flexible layer;

forming a light emitting device on the flexible layer;

irradiating the base by laser light to form carbides in the bottom of the flexible layer surrounding the nanoparticles, and peeling off the carbides and the base to form a rough structure on one surface of the flexible layer; and

adhering a substrate on the bottom of the flexible layer, and sequentially stacking up a touch panel, a polarizer, and a cover plate on the light emitting device to form the light emitting panel.

The step of forming the flexible layer on the base and the step of forming the nanoparticles in the bottom of the flexible layer include:

coating a solution having the nanoparticles doped therein on the base, and curing the solution to form the nanoparticles in the bottom of the flexible layer.

Before the step of adhering the substrate on the bottom of the flexible layer and the step of sequentially stacking up the touch panel, the polarizer, and the cover plate on the light emitting device to form the light emitting panel, the method further includes:

cleaning the bottom of the flexible layer to eliminate the nanoparticles.

A section shape of each of the carbides is one of an arc, a circle, a square, and a trapezoid.

Please refer to FIG. 6. FIG. 6 illustrates a flow chart of a method for manufacturing a light emitting panel provided by an embodiment of the present disclosure. An embodiment of the present disclosure further provides the method for manufacturing the light emitting panel configured to manufacture the above light emitting panel. The method includes the following steps.

In step S110, a base is provided.

The base herein is generally a glass base.

In step S120, a flexible layer is formed on the base, and nanoparticles are formed in a bottom of the flexible layer.

In detail, the step of forming the flexible layer on the base includes: coating a solution having the nanoparticles doped therein on the base, and curing the solution to form the nanoparticles in the bottom of the flexible layer.

It can be understood that a general method for forming the flexible layer includes: coating a flexible material solution on the base; and performing ultraviolet curing (UV curing). In order to dope the nanoparticles in the bottom of the flexible layer, the nanoparticles may be doped in the flexible material solution. The nanoparticles sink in the bottom of the flexible layer. Then, the UV curing is performed, so that the nanoparticles are formed in the bottom of the flexible layer.

A diameter of each of the nanoparticles is ranged from 1 nanometer to 2000 nanometers. A shape of each of the nanoparticles is one of a circle, a square, a triangle, and a trapezoid. A material of each of the nanoparticles is one of gold, silver, and aluminum but is not limited herein.

In step S130, a light emitting device is formed on the flexible layer.

In step S140, the base is irradiated by laser to form carbides in the bottom of the flexible layer surrounding the nanoparticles, and the carbides and the base are peeled off to form a rough structure on one surface of the flexible layer.

In detail, when incident light irradiated by the laser light irradiates surfaces of the nanoparticles, free electrons on the surfaces of the nanoparticles and an incident electromagnetic wave together generate coherent oscillation at the same frequency, thereby generating an electromagnetic surface wave. Since the surfaces of the nanoparticles and the incident electromagnetic wave are collectively oscillated, energy of the incident light is effectively coupled to the surfaces of the nanoparticles in a wavelength range. Interaction of the energy of the incident light and ohmic loss of the metal nanoparticles may convert the energy of the incident light into thermal energy surrounding peripheries of the nanoparticles. That is, the nanoparticles have stronger thermal effect when the nanoparticles have a specific shape and a specific size and are irradiated by light having a specific wavelength. An oscillation wavelength of generating the thermal effect is related to parameters including the material, the size, and the shape of the nanoparticles. A specific oscillation wavelength may be selected by changing the above-mentioned parameters.

When the laser light irradiates, the laser light passes through the base and irradiates the bottom of the flexible layer. The nanoparticles in the bottom of the flexible layer interact with the laser light to generate the thermal effect. The flexible material surrounding the nanoparticles is carbonized, so that carbides are generated. Furthermore, interaction (e.g., Van der Waals force) of the flexible layer and the base is also destroyed to implement to peel off the carbides and the base by the laser light.

In some embodiments, a section shape of each of the carbides is one of an arc, a circle, a square, and a trapezoid.

After the carbides and the base are peeled off by the laser light, the bottom of the flexible layer is cleaned to eliminate residual nanoparticles to form concave portions.

In step S150, a substrate is adhered on the bottom of the flexible layer, and a touch panel, a polarizer, and a cover plate are sequentially stacked up on the light emitting device to form the light emitting panel.

An embodiment of the present disclosure further provides a light emitting panel including a substrate, a flexible layer, a light emitting device, and a cover plate which are sequentially stacked up from bottom to top.

A rough structure is formed on one surface of the flexible layer facing the substrate, and the rough structure includes a plurality of concave portions which are arranged. An interval is formed between two adjacent ones of the concave portions. A touch panel and a polarizer are disposed between the light emitting device and the cover plate, and the polarizer is disposed on the touch panel.

An embodiment of the present disclosure provides a method for manufacturing a light emitting panel including providing a base; forming a flexible layer on the base, and forming nanoparticles in a bottom of the flexible layer; forming a light emitting device on the flexible layer; and irradiating the base by laser light to form carbides in the bottom of the flexible layer surrounding the nanoparticles, and peeling off the carbides and the base to form a rough structure on one surface of the flexible layer; and adhering a substrate on the bottom of the flexible layer, and sequentially stacking up a touch panel, a polarizer, and a cover plate on the light emitting device to form the light emitting panel. Mechanical damages or wrinkles among layers during a bending process can be decreased by changing the position of the stress neutral surface when the light emitting panel is bent. Yield rate of the light emitting panel can be increased.

The light emitting panel and the method for manufacturing the light emitting panel provided by the embodiments of the present disclosure are described in detail as above. The embodiments are used to describe the principle and the implementations of the present disclosure. It should be understood that present disclosure is not limited to the exemplary examples. One of ordinary skill in the art may achieve equivalent improvements or replacements according to the above description. The equivalent improvements and replacements should be considered to belong to the protection scope of the present disclosure.

1. A light emitting panel, comprising:
a substrate, a flexible layer, a light emitting device, and a cover plate which are sequentially stacked up from bottom to top;
wherein a rough structure is formed on one surface of the flexible layer facing the substrate, and the rough structure comprises a plurality of concave portions which are arranged.

2. The light emitting panel of claim 1, wherein an interval is formed between two adjacent ones of the concave portions.

3. The light emitting panel of claim 2, wherein a density of the concave portions on the flexible layer is ranged from 10⁴ to 10⁸ per square centimeter, a length of a first opening of each of the concave portions in a horizontal direction is ranged from 1 nanometer to 5000 nanometers, and a length of a second opening of each of the concave portions in a vertical direction is ranged from 100 nanometers to 5000 nanometers.

4. The light emitting panel of claim 2, wherein a section shape of each of the concave portions is one of an arc, a circle, a square, and a trapezoid.

5. The light emitting panel of claim 1, wherein a touch panel and a polarizer are disposed between the light emitting device and the cover plate, and the polarizer is disposed on the touch panel.

6. A method for manufacturing a light emitting panel, comprising:
providing a base;
forming a flexible layer on the base, and forming nanoparticles in a bottom of the flexible layer;
forming a light emitting device on the flexible layer;
irradiating the base by laser light to form carbides in the bottom of the flexible layer surrounding the nanoparticles, and peeling off the carbides and the base to form a rough structure on one surface of the flexible layer; and
adhering a substrate on the bottom of the flexible layer, and sequentially stacking up a touch panel, a polarizer, and a cover plate on the light emitting device to form the light emitting panel.

7. The method for manufacturing the light emitting panel of claim 6, wherein the step of forming the flexible layer on the base and the step of forming the nanoparticles in the bottom of the flexible layer comprise:
coating a solution having the nanoparticles doped therein on the base, and curing the solution to form the nanoparticles in the bottom of the flexible layer.

8. The method for manufacturing the light emitting panel of claim 6, wherein before the step of adhering the substrate on the bottom of the flexible layer and the step of sequentially stacking up the touch panel, the polarizer, and the cover plate on the light emitting device to form the light emitting panel, the method further comprises:
cleaning the bottom of the flexible layer to eliminate the nanoparticles.

9. The method for manufacturing the light emitting panel of claim 6, wherein a section shape of each of the carbides is one of an arc, a circle, a square, and a trapezoid.

10. A display device, comprising a housing and a light emitting panel disposed on the housing, and the light emitting panel comprising:
a substrate, a flexible layer, a light emitting device, and a cover plate which are sequentially stacked up from bottom to top;
wherein a rough structure is formed on one surface of the flexible layer facing the substrate, and the rough structure comprises a plurality of concave portions which are arranged.

11. The display device of claim 10, wherein an interval is formed between two adjacent ones of the concave portions

12. The display device of claim 11, wherein a density of the concave portions on the flexible layer is ranged from 10⁴ to 10⁸ per square centimeter, a length of a first opening of each of the concave portions in a horizontal direction is ranged from 1 nanometer to 5000 nanometers, and a length of a second opening of each of the concave portions in a vertical direction is ranged from 100 nanometers to 5000 nanometers.

13. The display device of claim 11, wherein a section shape of each of the concave portions is one of an arc, a circle, a square, and a trapezoid.

14. The display device of claim 10, wherein a touch panel and a polarizer are disposed between the light emitting device and the cover plate, and the polarizer is disposed on the touch panel.

15. (canceled)
